(19) United States
(12) Patent Application Publication
(10) Pub. No.: US 2017/0025378 A1
(43) Pub. Date: Jan. 26, 2017

(54) METHOD OF BONDING A BUMP OF A SEMICONDUCTOR PACKAGE AND APPARATUS FOR PERFORMING THE SAME

(71) Applicant: Samsung Electronics Co., Ltd., Suwon-si (KR)

(72) Inventor: Bong-Ken YU, Hwaseong-si (KR)

(21) Appl. No.: 15/095,012

(22) Filed: Apr. 8, 2016

(30) Foreign Application Priority Data
Jul. 23, 2015 (KR) 10-2015-0104044

(51) Int. Cl. H01L 23/00

(52) U.S. Cl. CPC H01L 24/92; H01L 24/81; H01L 24/83; H01L 24/75; H01L 2224/92125; H01L 2224/812; H01L 2224/81203; H01L 2224/832; H01L 2224/81191; H01L 2224/83191; H01L 2224/755; H01L 2224/75252; H01L 2224/7565; H01L 2224/75251

(57) ABSTRACT

In a method of bonding a bump of a bump of a semiconductor package, a semiconductor chip including the bump and a non-conductive film (NCF) may be on standby over a package substrate on a bonding stage. The semiconductor chip may be cooled. The semiconductor chip may be positioned on the package substrate. The semiconductor chip may be heated to a bonding temperature to bond the bump to the package substrate. Thus, the NCF of the semiconductor chip, which may be on standby at the buffer, may not be melt.

### CROSS-RELATED APPLICATION

This application claims priority under 35 USC §119 to Korean Patent Application No. 2015-0104044, filed on Jul. 23, 2015 in the Korean Intellectual Property Office (KIPO), the contents of which are herein incorporated by reference in their entirety.

### BACKGROUND

1. Field

Example embodiments of the inventive concept relate to a method of bonding a bump of a semiconductor package and an apparatus for performing the same. More particularly, example embodiments of the inventive concept relate to a method of bonding a bump on a bonding pad of a semiconductor chip to a package substrate, and an apparatus for performing the same.

2. Description of the Related Art

Generally, a semiconductor chip may be electrically connected to a package substrate via a bump. The bump may be bonded to the package substrate by a bonding process using a high heat. During the bonding process, the package substrate may be bent due to a difference in thermal expansion coefficients of the semiconductor chip and the package substrate. In order to prevent the package substrate from being bent, a non-conductive film (NCF) may be attached to the bump.

According to related arts, while a bonding head heat the semiconductor chip at a bonding temperature to bond the semiconductor chip to the package substrate, a next semiconductor chip may be on standby at a buffer. Here, the bonding temperature may be higher than a melting point of the NCF. When the high heat of the bonding head is transferred to the buffer, the NCF of the next semiconductor chip in the buffer may melt before the bonding process. Thus, the bonding process may be stopped until the temperature of the bonding head is decreased to a temperature below the melting point of the NCF. As a result, the bonding process may have low productivity.

### SUMMARY

According to example embodiments of the inventive concept, there may be provided a method of bonding a bump of a semiconductor package. In the method of bonding the bump of the semiconductor package, a semiconductor chip including the bump and a non-conductive film (NCF) may be on standby over a package substrate on a bonding stage.

The semiconductor chip may be cooled. The semiconductor chip may be positioned on the package substrate. The semiconductor chip may be heated to a bonding temperature to bond the bump to the package substrate.

In example embodiments, the cooling the semiconductor chip may include cooling the semiconductor chip to a temperature below a melting point of the NCF.

In example embodiments, the cooling the semiconductor chip may include supplying a refrigerant to the semiconductor chip.

In example embodiments, the cooling the semiconductor chip may include supplying a cooling air to the semiconductor chip.

In example embodiments, the method may further include heating the package substrate.

In example embodiments, the heating the package substrate may include heating the package substrate to a temperature between the bonding temperature and the melting point.

In example embodiments, the semiconductor chip may further include a plug formed in the semiconductor chip and electrically connected with the bump.

According to example embodiments, there may be provided a method of bonding a bump of a bump of a semiconductor package. In the method of bonding the bump of the semiconductor package, a package substrate may be heated. A semiconductor chip may be placed over the package substrate. The semiconductor chip may include the bump and a non-conductive film (NCF). The semiconductor chip may be cooled to a temperature below a melting point of the NCF. The semiconductor chip may be placed on the package substrate. The semiconductor chip may be heated to a bonding temperature to bond the bump to the package substrate.

In example embodiments, the NCF may cover the bump. In example embodiments, the cooling the semiconductor chip may include supplying a refrigerant to the semiconductor chip.

In example embodiments, the cooling the semiconductor chip may include supplying a cooling air to the semiconductor chip.

In example embodiments, the heating a package substrate may include heating the package substrate to a temperature between the bonding temperature and a melting point of the NCF.

According to example embodiments, there may be provided an apparatus for bonding a bump of a bump of a semiconductor package. The apparatus may include a bonding stage, a buffer, a cooling unit and a bonding head. A package substrate may be placed on the bonding stage. The buffer may be arranged over the bonding stage. The buffer may be configured to allow a semiconductor chip including the bump and a non-conductive film (NCF) to be on standby thereon. The cooling unit may cool the semiconductor chip on the buffer. The bonding head may heat the semiconductor chip to a bonding temperature to bond the bump to the package substrate.

In example embodiments, the cooling unit may include a cooling passageway formed in the buffer, and a cooling source for supplying a refrigerant or a cooling air, to the cooling passageway.

In example embodiments, the apparatus may further comprise a gripper configured to transfer the semiconductor chip to the buffer.

In example embodiments, the apparatus may further comprise a transferring unit configured to move the gripper.

In example embodiments, the cooling unit may cool the semiconductor chip to a temperature below a melting point of the NCF.

In example embodiments, the apparatus may further include a heater configured to heat the bonding stage.

In example embodiments, the apparatus may further include a driving unit configured to move the cooling unit in a horizontal direction and a vertical direction.

In example embodiments, the apparatus may further include a lifting unit configured to move the bonding head in a vertical direction.

### BRIEF DESCRIPTION OF THE DRAWINGS

Example embodiments will be more clearly understood from the following detailed description taken in conjunction with the accompanying drawings. FIGS. 1 to 8 represent non-limiting, example embodiments as described herein.

FIG. 1 is a cross-sectional view illustrating an apparatus for bonding a bump of a semiconductor package in accordance with example embodiments of the inventive concept;

FIG. 2 is a cross-sectional view illustrating a buffer of the apparatus in FIG. 1 in accordance with example embodiments of the inventive concept;

FIG. 3 is a cross-sectional view illustrating a buffer of a bonding apparatus in accordance with example embodiments of the inventive concept; and

FIGS. 4 to 8 are cross-sectional views illustrating a method of bonding a bump of a semiconductor chip to a package substrate using the apparatus in FIG. 1 in accordance with example embodiments of the inventive concept.

### DETAILED DESCRIPTION OF THE EMBODIMENTS

Various example embodiments will be described more fully hereinafter with reference to the accompanying drawings, in which some example embodiments are shown. These example embodiments are provided so that this disclosure will be thorough and complete, and will fully convey the scope of the inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms.

These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the inventive concept will be explained in detail with reference to the accompanying drawings.

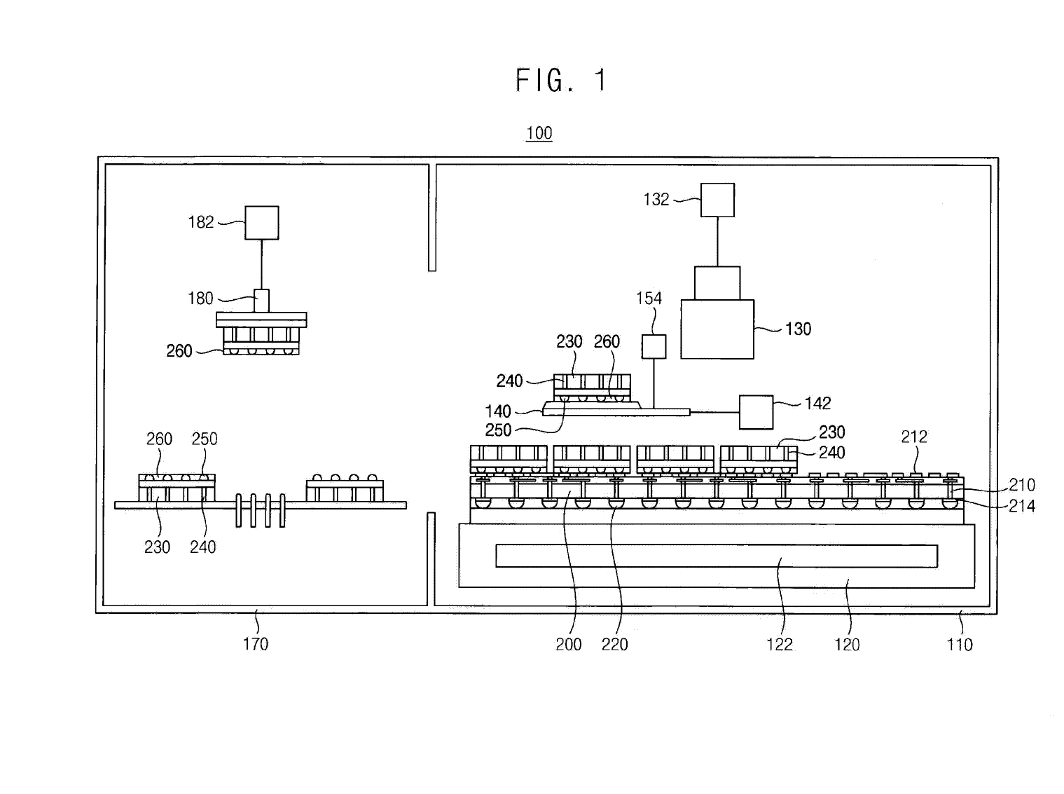

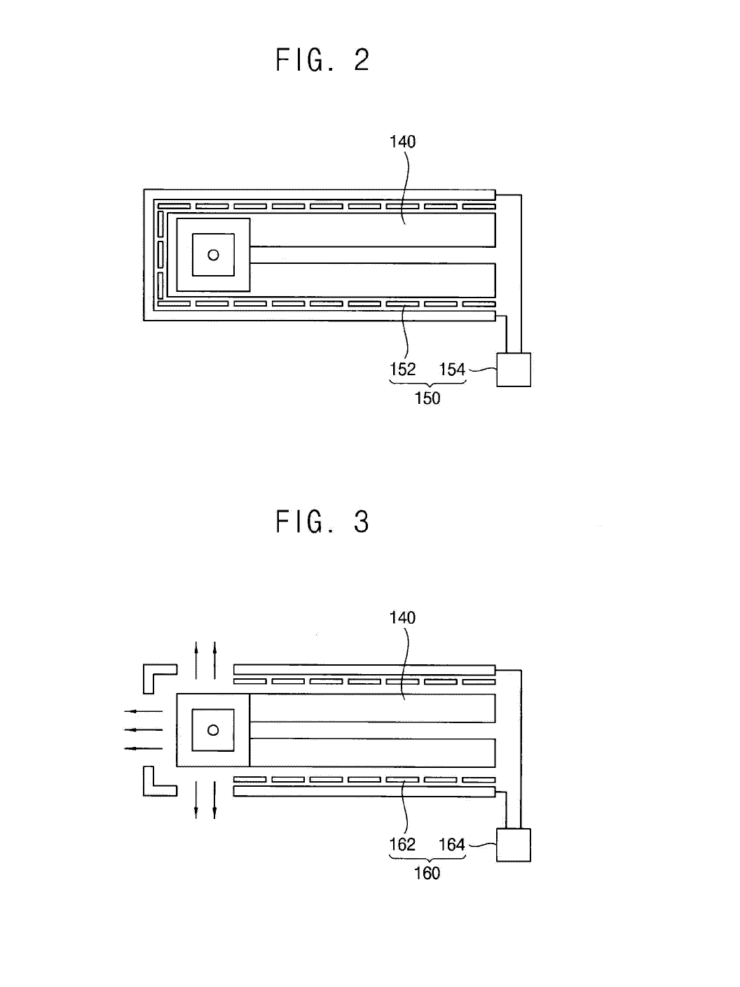

FIG. 1 is a cross-sectional view illustrating an apparatus for bonding a bump of a semiconductor package in accordance with example embodiments of the inventive concept, and FIG. 2 is a cross-sectional view illustrating a buffer of the apparatus in FIG. 1 in accordance with example embodiments of the inventive concept.

Referring to FIGS. 1 and 2, an apparatus 100 for a bump of a semiconductor package in accordance with example embodiments of the inventive concept may include a bonding chamber 110, a bonding stage 120, a bonding head 130, a buffer 140 and a cooling unit 150.

The bonding apparatus 100 may bond bumps 250 of semiconductor chips 230 to a package substrate 200. The package substrate 200 may include internal circuits 210. Each of the internal circuits 210 may include an upper pad 212 exposed through an upper surface of the package substrate 200, and a lower pad 214 exposed through a lower surface of the package substrate 200. The bumps 250 may be bonded to the upper pads 212. External terminals 220 such as solder balls may be mounted on the lower pads 214.

The bumps 250 may be arranged on an active face of the semiconductor chip 230. The bumps 250 may be electrically connected with circuit structures in the semiconductor chip 230. A non-conductive film (NCF) 260 may be attached to the active face of the semiconductor chip 230. Thus, the NCF 260 may be configured to cover the bumps 250.

The NCF 260 may function to suppress the package substrate 200 from being bent due to a difference in thermal expansion coefficients of the package substrate 200 and the semiconductor chip 230 during a bonding process. Further, the NCF 260 may be dissolved during the bonding process to attach the semiconductor chip 230 to the package substrate 200. Furthermore, when the NCF 260 is stiffened after the bonding process, the stiffened NCF 260 may function as an underfilling layer configured to fill spaces between the bumps 250. The NCF 260 may have a melting point at which the NCF 260 can be melted by a bonding temperature of the bonding process. The melting point of the NCF 260 may vary in accordance with materials of the NCF 260. Thus, when the NCF 260 melts in the buffer 140 before the bonding process, the functions of the NCF 260 may be lost.

Additionally, in order to form a multi-chip package, plugs 240 may be formed to vertically extend in the semiconductor chip 230. The plugs 240 may be connected to the bumps 250. An upper semiconductor chip may be stacked on the semiconductor chip 230 via bumps. The bumps of the upper semiconductor chip may be connected to the plugs 240. The bumps of the upper semiconductor chip may be bonded to the plugs 240 of the semiconductor chip 230 using the bonding apparatus 100.

The bonding stage 120 may be arranged on a bottom surface of the bonding chamber 110. The package substrate 200 may be placed on an upper surface of the bonding stage 120. Additionally, a heater 122 may be built in the bonding stage 120. The heater 122 may heat the package substrate 200. The heater 122 may provide the package substrate 200 with a temperature between the bonding temperature and the melting point of the NCF 260.

The bonding head 130 may be arranged over the bonding stage 120. The bonding head 130 may heat the semiconductor chip 230 to the bonding temperature. Further, the bonding head 130 may compress the semiconductor chip 230 to the package substrate 200.

That is, the bonding head 130 may thermally compress the semiconductor chip 230 to the package substrate 200 to bond the bumps 250 to the upper pads 212. As mentioned above, the NCF 260 may be dissolved at the bonding temperature of the bonding head 130.

A lifting unit 132 may lift the bonding head 130. The lifting unit 132 may downwardly move the bonding head 130 toward the bonding stage 120 so that the bonding head 130 may thermally compress the semiconductor chip 230 to the package substrate 200. The lifting unit 132 may include a motor and/or a cylinder.

The buffer 140 may be arranged over the bonding stage 120. When the bonding head 130 bonds the semiconductor chip 230 to the package substrate 200, a next semiconductor chip 230 may be on standby on the buffer 140. Heat of the bonding temperature of the bonding head 130 may be transferred to the next semiconductor chip 230 in the buffer 140 during the bonding process so that the NCF 260 of the next semiconductor chip 230 may be dissolved.

In order to prevent the NCF 260 of the next semiconductor chip 230 from being dissolved, the cooling unit 150 may cool the buffer 140. The cooling unit 150 may cool the buffer 140 to a temperature below the melting point of the NCF 260. Thus, the next semiconductor chip 230 in the buffer 140 may be cooled by the cooling unit 150 to prevent the NCF 260 of the next semiconductor chip 230 from being dissolved. In other words, because the heat of the bonding temperature of the bonding head 130 is continuously transferred to the buffer 140, the cooling unit 150 may continuously cool the buffer 140. As a result, it may not be required to stop the bonding process until the temperature of the bonding head 130 decreases to the temperature below the melting point of the NCF 260 so that the bonding apparatus 100 may have improved productivity.

The buffer 140 may have a rectangular plate shape. The cooling unit 150 may be a water-cooling type. Thus, the cooling unit 150 may include a cooling passageway 152 and a cooling source 154. The cooling passageway 152 may be formed in the buffer 140. The cooling source 154 may supply a refrigerant to the cooling passageway 152. The refrigerant supplied to the cooling passageway 152 may be returned to the cooling source 154. Thus, the cooling passageway 152 may have a closed loop shape that is extended from the cooling source 154 and is returned to the cooling source 154.

A preliminary chamber 170 may be arranged adjacent to the bonding chamber 110. The semiconductor chips 230 may be received in the preliminary chamber 170. A gripper 180 may be arranged in the preliminary chamber 170. The gripper 180 may transfer the semiconductor chips 230 one-by-one to the buffer 140. A transferring unit 182 may transfer the gripper 180 in both of a horizontal direction and a vertical direction. A driving unit 142 may move the buffer 140 in both of the horizontal direction and the vertical directions. The transferring unit 182 and the driving unit 142 may include a motor and/or a cylinder.

When the transferring unit 182 transfers the gripper 180 to the buffer 140, the buffer 140 may not be moved. In this case, the bonding apparatus 100 may not include the driving unit 142 for moving the buffer 140. In contrast, when the driving unit 142 may move the buffer 140 to the gripper 180, the gripper 180 may not move. In this case, the transferring unit 182 may not be connected to the gripper 180. The gripper 180 may transfer the semiconductor chip 230 between the preliminary chamber 170 and the bonding chamber 110. Thus, the transferring unit 182 may transfer the gripper 180 to the bonding chamber 110. The driving unit 142 may move the buffer 140 to the preliminary chamber 170.

FIG. 3 is a cross-sectional view illustrating a buffer of a bonding apparatus in accordance with example embodiments of the inventive concept.

A bonding apparatus of FIG. 3 may include elements substantially the same as those of the bonding apparatus 100 in FIG. 1 except for a cooling unit. Thus, the same reference numerals may refer to the same elements and any further illustrations with respect to the same elements may be omitted herein for brevity.

Referring to FIG. 3, a cooling unit 160 may be an air-cooling type. The cooling unit 160 may include a cooling passageway 162 and a cooling source 164. The cooling passageway 162 may be formed in the buffer 140. The cooling source 164 may supply a cooling air to the cooling passageway 162. Because it is not be required to return the cooling air to the cooling source 164, the cooling passageway 162 may have an opened loop shape extended from the cooling source 154 and opened through the buffer 140.

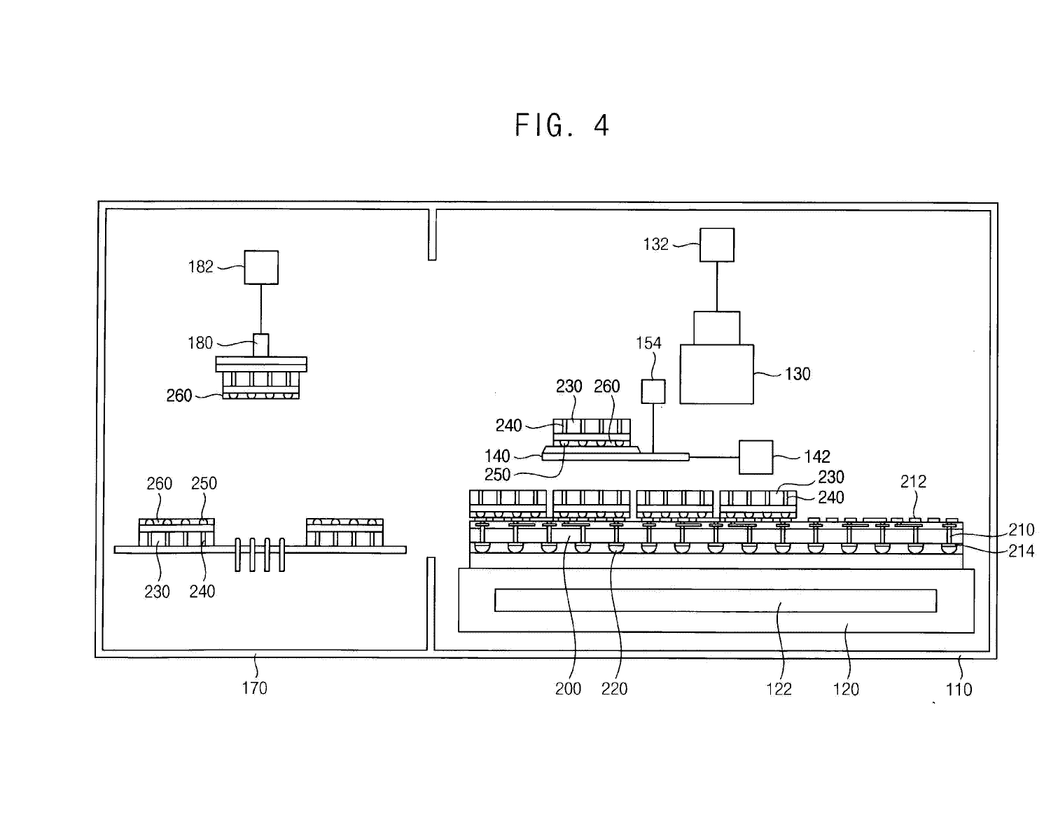

FIGS. 4 to 8 are cross-sectional views illustrating a method of bonding a bump of a semiconductor chip to a package substrate using the apparatus in FIG. 1 in accordance with example embodiments of the inventive concept.

Referring to FIG. 4, the bonding head 130 may bond the bumps 250 of the first semiconductor chip 230 to the package substrate 200. The second semiconductor chip 230 may be on standby on the buffer 230. The third semiconductor chip 230 may be gripped by the gripper 180. The package substrate 200 may be placed on the upper surface of the bonding stage 120. The heater 122 may heat the package substrate 200.

The bonding head 130 may compress the first semiconductor chip 230 to the package substrate 200. Further, the bonding head 130 may heat the first semiconductor chip 230 to the bonding temperature. Thus, the heat of the bonding temperature may be transferred to the second semiconductor chip 230 in the buffer 140. However, the cooling unit 150 may continuously cool the buffer 140 to the temperature below the melting point of the NCF 260 so that the NCF 260 of the second semiconductor chip 230 may not be dissolved.

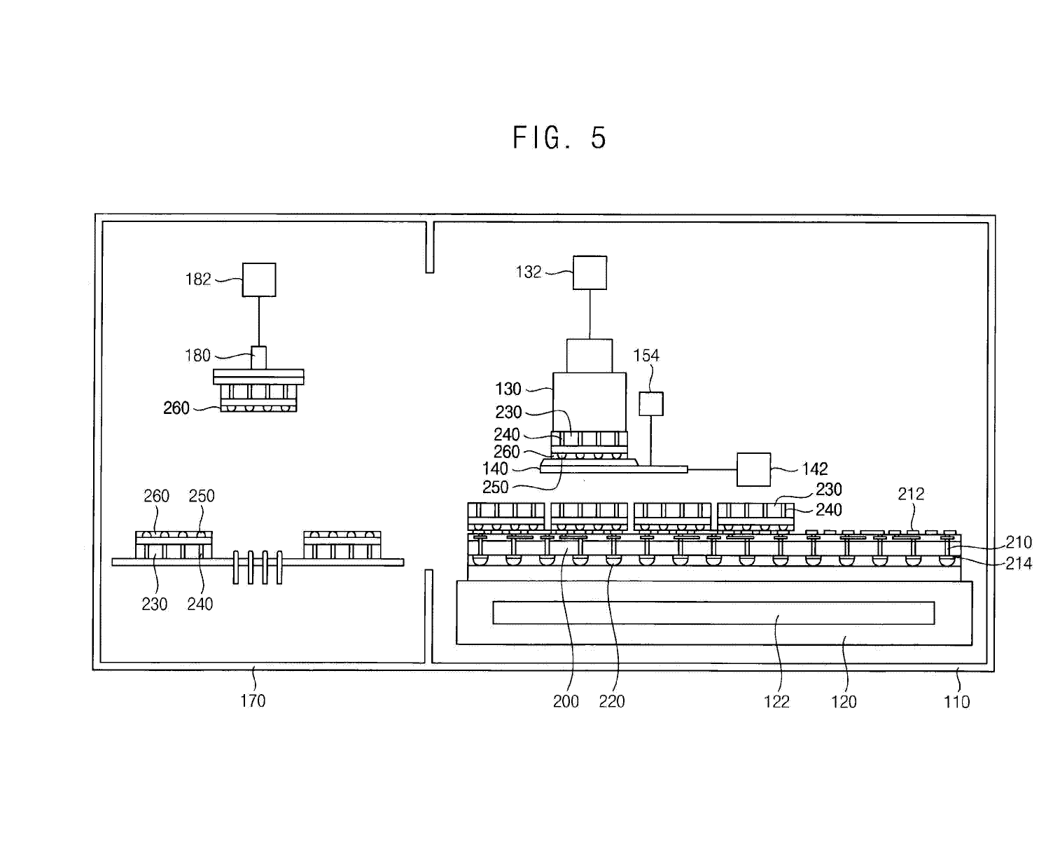

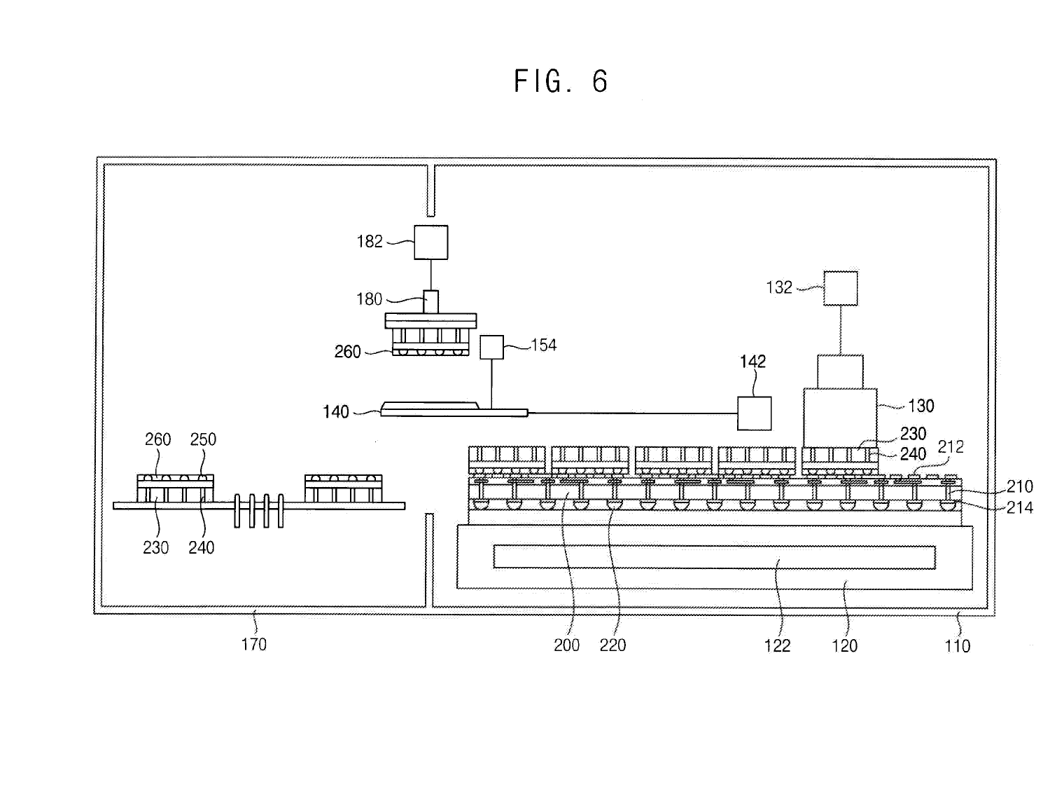

Referring to FIG. 5, after the first semiconductor chip 230 may be bonded to the package substrate 200, the lifting unit 132 may upwardly move the bonding head 130. The driving unit 142 may move the buffer 140 to a region under the bonding head 130. Thus, the second semiconductor chip 230 in the buffer 140 may be positioned under the bonding head 130.

The lifting unit 132 may downwardly move the bonding head 130 toward the buffer 140. The bonding head 130 may hold the second semiconductor chip 230. Because the cooling unit 150 continuously cools the buffer 140 to the temperature below the melting point of the NCF 260, during holding the second semiconductor chip 240 by the bonding head 130, the bonding temperature of the bonding head 130 may not be decreased to the temperature below the melting point of the NCF 260. That is, the bonding head 130 may still have the bonding temperature.

Referring to FIG. 6, the lifting unit 132 may downwardly move the bonding head 130 with the second semiconductor chip 230 to the bonding stage 120. The bonding head 130 may thermally compress the second semiconductor chip 230 to the package substrate 200 to bond the bumps 250 to the upper pads 212.

When the bonding head 130 bonds the second semiconductor chip 230 to the package substrate 200, the transferring unit 182 may transfer the gripper 180 with the third semiconductor chip 230 to the bonding chamber 110. The driving unit 142 may move the buffer 140 toward the preliminary chamber 170. The gripper 180 may transfer the third semiconductor chip 230 to the buffer 140.

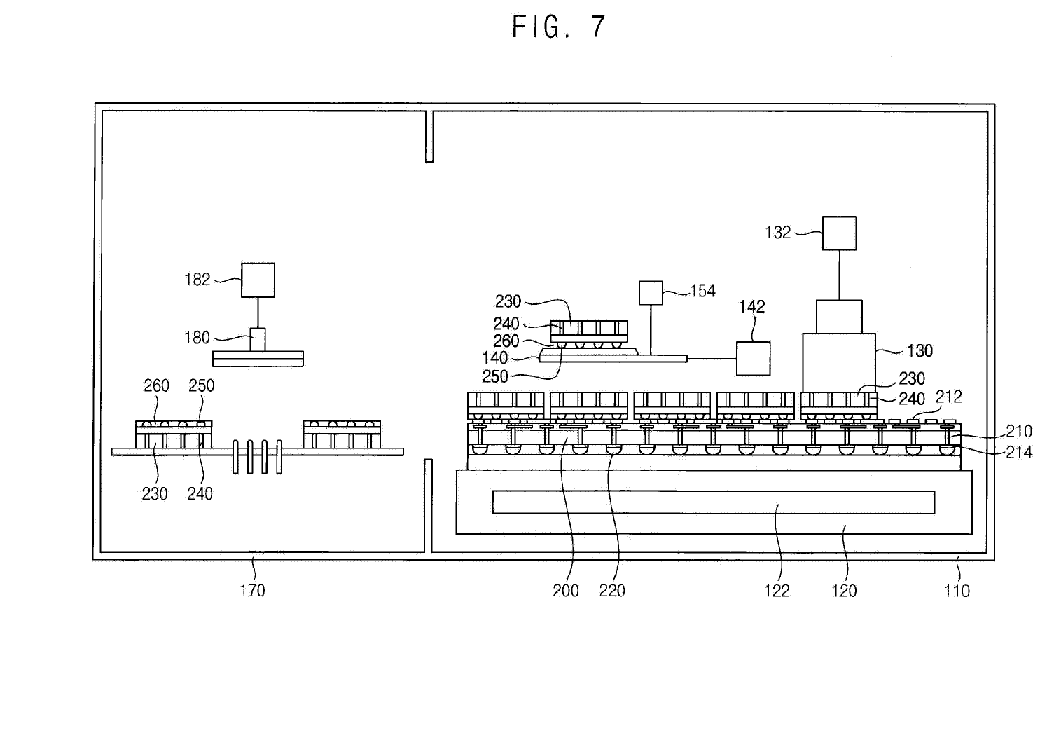

Referring to FIG. 7, the driving unit 142 may move the buffer 140 into the bonding chamber 110. Thus, the third semiconductor chip 230 may be on standby in the buffer 140. The cooling unit 150 may continuously cool the buffer 140 so that the NCF 260 of the third semiconductor chip 230 may not be dissolved.

The lifting unit 182 may downwardly move the gripper 180. The gripper 180 may grip the fourth semiconductor chip 230. The gripping operation of the gripper 180 and the returning operation of the buffer 140 may be performed simultaneously with each other.

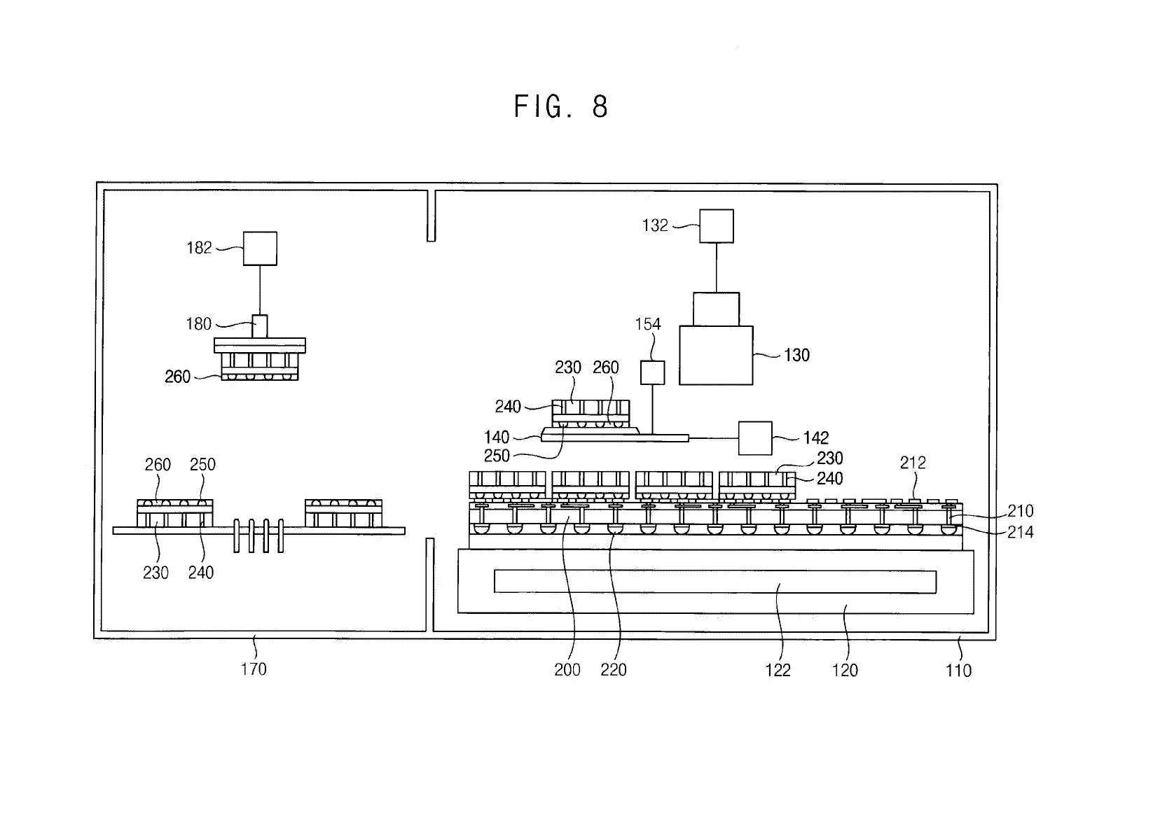

Referring to FIG. 8, the transferring unit 182 may upwardly move the gripper 180 with the fourth semiconductor chip 230. When the bonding head 130 may bond the semiconductor chip 230 to the package substrate 200, the above-mentioned processes illustrated with reference to FIGS. 4 to 8 may be repeated.

According to example embodiments, the cooling unit may cool the semiconductor chip to the temperature below the melting point of the NCF. Thus, the NCF of the semiconductor chip, which may be on standby at the buffer, may not be melt. As a result, because it is not be required to stop the bonding process until the temperature of the bonding heat is decreased to the temperature below the melting point of the NCF, the bonding process may be continuously performed so that the bonding process may have improved productivity.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of bonding a bump of a semiconductor package, the method comprising:
placing a semiconductor chip over a package substrate on a bonding stage, a semiconductor chip including the bump and a non-conductive film (NCF);
cooling the semiconductor chip;
placing the semiconductor chip on the package substrate; and
heating the semiconductor chip to a bonding temperature to bond the bump to the package substrate.

2. The method of claim 1, wherein the cooling the semiconductor chip comprises cooling the semiconductor chip to a temperature below a melting point of the NCF.

3. The method of claim 2, wherein the cooling the semiconductor chip comprises supplying a refrigerant to the semiconductor chip.

4. The method of claim 2, wherein the cooling the semiconductor chip comprises supplying a cooling air to the semiconductor chip.

5. The method of claim 1, further comprising heating the package substrate.

6. The method of claim 5, wherein the heating the package substrate comprises heating the package substrate to a temperature between the bonding temperature and a melting point of the NCF.

7. The method of claim 1, wherein the semiconductor chip further comprises a plug formed in the semiconductor chip and electrically connected with the bump.

8. A method of bonding a bump of a semiconductor package, the method comprising:
heating a package substrate;
placing a semiconductor chip, which includes the bump and a non-conductive film (NCF), over the package substrate;
cooling the semiconductor chip to a temperature below a melting point of the NCF;
placing the semiconductor chip on the package substrate; and
heating the semiconductor chip to a bonding temperature to bond the bump to the package substrate.

9. The method of claim 8, wherein the NCF covers the bump.

10. The method of claim 8, wherein the cooling the semiconductor chip comprises supplying a refrigerant to the semiconductor chip.

11. The method of claim 8, wherein the cooling the semiconductor chip comprises supplying a cooling air to the semiconductor chip.

12. The method of claim 8, wherein the heating a package substrate comprises heating the package substrate to a temperature between the bonding temperature and a melting point of the NCF.

13. An apparatus for bonding a bump of a semiconductor package, the apparatus comprising:
a bonding stage configured to receive a package substrate;
a buffer arranged over the bonding stage, the buffer configured to allow a semiconductor chip, which includes the bump and a non-conductive film (NCF), to be on standby thereon;
a cooling unit configured to cool the semiconductor chip on the buffer; and
a bonding head configured to heat the semiconductor chip to a bonding temperature to bond the bump to the package substrate.

14. The apparatus of claim 13, wherein the cooling unit comprises:
a cooling passageway formed in the buffer; and
a cooling source configured to supply a refrigerant or a cooling air to the cooling passageway.

15. The apparatus of claim 14, further comprising a gripper configured to transfer the semiconductor chip to the buffer.

16. The apparatus of claim 15, further comprising a transferring unit configured to move the gripper

17. The apparatus of claim 13, wherein the cooling unit cools the semiconductor chip to a temperature below a melting point of the NCF.

18. The apparatus of claim 13, further comprising a heater configured to heat the bonding stage.

19. The apparatus of claim 13, further comprising a driving unit configured to move the cooling unit in a horizontal direction and a vertical direction.

20. The apparatus of claim 13, further comprising a lifting unit configured to move the bonding head in a vertical direction.
